(19) United States
(12) Patent Application Publication
(10) Pub. No.: US 2009/0316373 A1
(43) Pub. Date: Dec. 24, 2009

(54) PCB having chips embedded therein and method of manfacturing the same

(75) Inventors: Dong Kuk Kim, Yongin-si (KR); Tae Hyun Kim, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO. LTD., Suwon (KR)

(21) Appl. No.: 12/230,942

(22) Filed: Sep. 8, 2008

(30) Foreign Application Priority Data
Jun. 19, 2008 (KR) 10-2008-0057851

(51) Int. Cl. H05K 1/18; H05K 3/36

(52) U.S. Cl. 361/764; 29/830

(57) ABSTRACT

Provided is a PCB having chips embedded therein, the PCB including a first core substrate that has a first chip embedded therein, the first chip having a plurality of first pads provided on the top surface thereof, and first circuit patterns provided on both surfaces thereof; a second core substrate that is disposed under the first core substrate so as to be spaced at a predetermined space from the first core substrate and has a second chip embedded therein, the second chip having a plurality of second pads provided on the bottom surface thereof, and second circuit patterns provided on both surfaces thereof; a first insulating layer that is laminated on the first core substrate and has a plurality of first conductive bumps formed therein, the first conductive bumps passing through the first insulating layer and being connected to the first circuit patterns and the first pads; a second insulating layer that is laminated between the first core substrate and the second core substrate and has a plurality of second conductive bumps formed therein, the second conductive bumps passing through the second insulating layer and connecting the first circuit patterns to the second circuit patterns; and a third insulating layer that is laminated under the second core substrate and has a plurality of third conductive bumps formed therein, the third conductive bumps passing through the third insulating layer and being connected to the second circuit patterns and the second pads.

### CROSS-REFERENCE TO RELATED APPLICATIONS

This application claims the benefit of Korean Patent Application No. 10-2008-0057851 filed with the Korea Intellectual Property Office on Jun. 19, 2008, the disclosure of which is incorporated herein by reference.

### BACKGROUND OF THE INVENTION

1. Field of the Invention

The present invention relates to a printed circuit board (PCB) having chips embedded therein and a method of manufacturing the same.

2. Description of the Related Art

Recently, as demand for high performance and miniaturization of electronic apparatuses increases, high-performance electronic parts are highly integrated. Therefore, demand for small-sized PCBs which can mount highly-integrated electronic parts is increasing. As the demand for small-sized PCBs increases, multilayer circuit boards are being developed, which electrically connect wiring lines formed in different layers or electronic parts and wiring lines through via holes.

Such multilayer circuit boards can not only reduce wiring lines which connect electronic parts, but can also achieve high-density wiring. Further, because of the mounting of electronic parts, the multilayer circuit boards can increase the surface area of a PCB, and have an excellent electrical characteristic.

In particular, demand for a PCB having electronic parts embedded therein gradually increases. Since the electronic parts are embedded in the PCB, the miniaturization, high integration, and high performance of the PCB can be achieved.

In a conventional PCB having chips embedded therein, a carrier film is attached to a perforated core substrate, and a chip is positioned. Further, an insulating layer formed of prepreg is laminated on a surface of the core substrate which is opposite to the surface to which the carrier film is attached, and the carrier film is peeled off. Then, a prepreg layer is laminated on the surface from which the carrier film is peeled off.

Next, via holes are formed in portions of the PCB, where electric connection is required, through a laser drill method or the like, and copper plating is performed.

However, when the via holes are formed through such a laser drill method, it is difficult to process the via holes at accurate positions, because of a positional error of the chip or tolerance of a laser drill. Therefore, connection defects may occur, thereby degrading a production yield and reliability.

### SUMMARY OF THE INVENTION

An advantage of the present invention is that it provides a PCB having chips embedded therein, in which insulating layers having conductive bumps corresponding to pads of chips and circuit patterns of core substrates are laminated on and under the core substrate having the chips embedded therein, thereby simplifying the manufacturing process and improving yield and reliability.

Another advantage of the invention is that it provides a method of manufacturing a PCB having chips embedded therein.

Additional aspects and advantages of the present general inventive concept will be set forth in part in the description which follows and, in part, will be obvious from the description, or may be learned by practice of the general inventive concept.

According to an aspect of the invention, a PCB having chips embedded therein comprises a first core substrate that has a first chip embedded therein, the first chip having a plurality of first pads provided on the top surface thereof, and first circuit patterns provided on both surfaces thereof; a second core substrate that is disposed under the first core substrate so as to be spaced at a predetermined space from the first core substrate and has a second chip embedded therein, the second chip having a plurality of second pads provided on the bottom surface thereof, and second circuit patterns provided on both surfaces thereof; a first insulating layer that is laminated on the first core substrate and has a plurality of first conductive bumps formed therein, the first conductive bumps passing through the first insulating layer and being connected to the first circuit patterns and the first pads; a second insulating layer that is laminated between the first core substrate and the second core substrate and has a plurality of second conductive bumps formed therein, the second conductive bumps passing through the second insulating layer and connecting the first circuit patterns to the second circuit patterns; and a third insulating layer that is laminated under the second core substrate and has a plurality of third conductive bumps formed therein, the third conductive bumps passing through the third insulating layer and being connected to the second circuit patterns and the second pads.

The PCB may further comprise copper foil patterns that are formed on the surfaces of the first and third insulating layers so as to be connected to the first and third conductive bumps.

The first core substrate may have a first cavity perforated in a predetermined portion thereof, and the first chip may be inserted into the first cavity.

The PCB may further comprise a first filler that is filled between the first chip and the first cavity so as to fix the first chip.

The second core substrate may have a second cavity perforated in a predetermined portion thereof, and the second chip may be inserted into the second cavity.

The PCB may further comprise a second filler that is filled between the second chip and the second cavity so as to fix the second chip.

The first pads may be one-to-one connected to the first conductive bumps.

The second pads may be one-to-one connected to the third conductive bumps.

The first to third conductive bumps may be formed of any one selected from the group consisting of conductive epoxy, Ag, Cu, Sn, Au, and Sn-based alloy. The Sn-based alloy may be composed of any one selected from the group consisting of AuSn, SnSb, SnAg, SnPb, SnBi, and SnIn.

The first and second pads may be balls or bumps formed of any one selected from the group consisting of Au, Cu, Sn, and Sn-based alloy.

The first to third insulating layers may be formed of prepreg or ABF (Ajinomoto Build-up Film).

According to another aspect of the invention, a PCB having chips embedded therein comprises a first core substrate that has a first chip embedded therein, the first chip having a plurality of first pads provided on the bottom surface thereof, and first circuit patterns provided on both surfaces thereof; a second core substrate that is disposed under the first core substrate so as to be spaced at a predetermined space from the first core substrate and has a second chip embedded therein, the second chip having a plurality of second pads provided on the bottom surface thereof, and second circuit patterns provided on both surfaces thereof; a first insulating layer that is laminated on the first core substrate and has a plurality of first conductive bumps formed therein, the first conductive bumps passing through the first insulating layer and being connected to the first circuit patterns; a second insulating layer that is laminated between the first core substrate and the second core substrate and has a plurality of second conductive bumps formed therein, the second conductive bumps passing through the second insulating layer and connecting the first circuit patterns and the first pads to the second circuit patterns; and a third insulating layer that is laminated under the second core substrate and has a plurality of third conductive bumps formed therein, the third conductive bumps passing through the third insulating layer and being connected to the second circuit patterns and the second pads.

The PCB may further comprise a third core substrate that is laminated on the first insulating layer and has a third chip embedded therein, the third chip having a plurality of third pads provided on the top surface thereof, and third circuit patterns provided on both surfaces thereof; and a fourth insulating layer that is laminated on the third core substrate and has a plurality of fourth conductive bumps formed therein, the fourth conductive bumps passing through the fourth insulating layer and being connected to the third circuit patterns and the third pads.

According to a further aspect of the invention, a method of manufacturing a PCB having chips embedded therein comprises: providing a first core substrate, the first core substrate having a first chip embedded therein, the first chip having a plurality of first pads provided on the top surface thereof, and first circuit patterns provided on both surfaces thereof; disposing a first copper foil layer and a second insulating layer above and under the first core substrate, the first copper foil layer having a first insulating layer provided on one surface thereof, the first insulating layer having a plurality of conductive bumps formed therein, the conductive bumps corresponding to the first circuit patterns and the first pads, the second insulating layer having a plurality of second conductive bumps formed therein, the second conductive bumps corresponding to the first circuit patterns; disposing a second core substrate under the second insulating layer, the second core substrate having a second chip embedded therein, the second chip having a plurality of second pads provided on the bottom surface thereof, and second circuit patterns provided on both surfaces thereof; disposing a third copper foil layer under the second core substrate, the third copper foil layer having a third insulating layer provided on one surface thereof, the third insulating layer having a plurality of third conductive bumps formed therein, the third conductive bumps corresponding to the second circuit patterns and the second pads; and laminating the first core substrate, the first copper foil layer, the second insulating layer, the second core substrate, and the third copper foil layer.

The method may further comprise: before the disposing of the first copper foil layer and the second insulating layer, forming the first conductive bumps on the first copper foil layer, and forming the second conductive bumps on a separate second copper foil layer; forming the first insulating layer on the first copper foil layer such that the first conductive bumps penetrate the first insulating layer so as to be exposed, and forming the second insulating layer on the second copper foil layer such that the second conductive bumps penetrate the second insulating layer so as to be exposed; and removing the second copper foil layer from the second insulating layer.

The first and second conductive bumps may be formed in a conical shape.

The method may further comprise: before the disposing of the third copper foil layer; forming the third conductive bumps on the third copper foil layer; and forming the third insulating layer on the third copper foil layer such that the third conductive bumps penetrate the third insulating layer so as to be exposed.

The method may further comprise: after the laminating of the first core substrate, the first copper foil layer, the second insulating layer, the second core substrate, and the third copper foil layer, heating and pressurizing the PCB.

The method may further comprise: after the heating and pressurizing of the PCB, partially removing the first and third copper foil layers so as to form copper foil patterns which are to be connected to the first and third conductive bumps.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a PCB having chips embedded therein according to a first embodiment of the invention;

FIG. 2 is a cross-sectional view of a PCB having chips embedded therein according to a second embodiment of the invention;

FIG. 3 is a cross-sectional view of a PCB having chips embedded therein according to a third embodiment of the invention; and

FIGS. 4 to 11 are process diagrams sequentially showing a method of manufacturing the PCB having chips embedded therein according to the first embodiment.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a PCB having chips embedded therein and a method of manufacturing the same of the present invention will be described in detail with reference to the accompanying drawings.

Structure of PCB Having Chips Embedded Therein

### First Embodiment

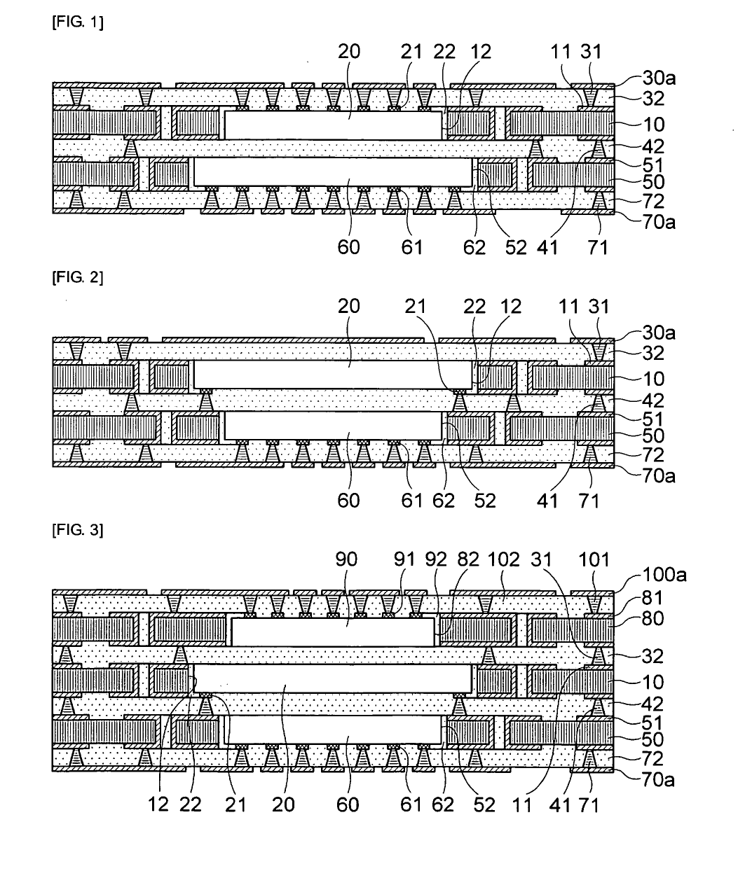

Referring to FIG. 1, a PCB having chips embedded therein according to a first embodiment of the invention will be described.

FIG. 1 is a cross-sectional view of a PCB having chips embedded therein according to a first embodiment of the invention.

As shown in FIG. 1, the PCB having chips embedded therein according to the first embodiment of the invention includes a first core substrate 10 which has a first chip 20 embedded therein, the first chip 20 having a plurality of first pads 21 provided on the top surface thereof, and first circuit patterns 11 provided on both surfaces thereof; a second core substrate 50 which is disposed under the first core substrate 10 so as to be spaced at a predetermined distance from the first core substrate 10 and has a second chip 60 embedded therein, the second chip 60 having a plurality of second pads 61 provided on the bottom surface thereof, and second circuit patterns 51 provided on both surfaces thereof; a first insulating layer 32 which is laminated on the first core substrate 10; a second insulating layer 42 which is laminated between the first and second core substrates 10 and 50; and a third insulating layer 72 which is laminated under the second core substrate 50.

The first insulating layer 32 has a plurality of first conductive bumps 31 formed therein, the first conductive bumps 31 passing through the first insulating layer 32. The first conductive bumps 31 are formed in positions corresponding to the first circuit patterns 11 provided on the top surface of the first core substrate 10 and the first pads 21 provided on the top surface of the first chip 20 so as to be connected to the first circuit patterns 11 and the first pads 21. In particular, the first conductive bumps 31 are formed so as to be one-to-one connected to the first pads 21.

The second insulating layer 42 has a plurality of second conductive bumps 41 formed therein, the second conductive bumps 41 passing through the second insulating layer 42. The second conductive bumps 41 connect the first circuit patterns 11 provided on the bottom surface of the first core substrate 10 to the second circuit patterns 51 provided on the top surface of the second core substrate 50.

The third insulating layer 72 has a plurality of third conductive bumps 71 formed therein, the third conductive bumps 71 passing through the third insulating layer 72. The third conductive bumps 71 are formed in positions corresponding to the second circuit patterns 51 provided on the bottom surface of the second core substrate 50 and the second pads 61 provided on the bottom surface of the second chip 60 so as to be connected to the second circuit patterns 51 and the second pads 61. In particular, the third conductive bumps 71 may be formed so as to be one-to-one connected to the second pads 61.

The first, second, and third conductive bumps 31, 41, and 71 may be formed of Ag, Cu, Sn, Au or Sn-based alloy with a low melting point. As for the Sn-based alloy, AuSn, SnSb, SnAg, SnPb, SnBi, or SnIn may be used.

The first, second, and third conductive bumps 31, 41, and 71 may be formed of conductive epoxy obtained by adding a conductive material into epoxy, instead of the above-described metals such as Ag and so on.

The first, second, and third insulating layers 32, 42, and 72 having the first, second, and third conductive bumps 31, 41, and 71 formed therein, respectively, may be formed of prepreg or ABF (Ajinomoto Build-up Film).

On the surfaces of the first and third insulating layers 32 and 72, first copper foil patterns 30a and third copper foil patterns 70a are respectively formed.

The first copper foil patterns 30a are connected to the first conductive bumps 31 formed in the first insulating layer 32, and the third copper foil patterns 70a are connected to the third conductive bumps 71 formed in the third insulating layer 72.

The first core substrate 10 has a first cavity 12 perforated in a predetermined portion thereof, and the first chip 20 is inserted into the first cavity 12. Between the first cavity 12 and the first chip 20, a first filler 22 is filled so as to fix the first chip 20.

The second core substrate 50 has a second cavity 52 perforated in a predetermined portion thereof, and the second chip 60 is inserted into the second cavity 52. Between the second cavity 52 and the second chip 60, a second filler 62 is filled so as to fix the second chip 60.

The first and second chips 20 and 60 may be active elements, passive elements, or ICs. In this case, the first and second chips 20 and 60 may have the same function or a different function from each other, and the sizes of the first and second chips 20 and 60 may be equal to or different from each other.

The first and second pads 21 and 61 provided on the first and second chips 20 and 60, respectively, may balls or bumps formed of Au, Cu, Sn, or Sn-based alloy with a low or high melting point.

The first and second fillers 22 and 62 may be formed of resin, epoxy, or prepreg.

As described above, the first and second core substrates 10 and 50 having the first and second chips 20 and 60 embedded therein serve to radiate heat generated from the first and second chips 20 and 60 to the outside, and may be formed of a metallic material such as Cu or Al.

The first and second circuit patterns 11 and 51 provided on the first and second core substrates 10 and 50, respectively, may be formed of a conductive material such as Cu.

In the PCB having chips embedded therein according to the first embodiment, the first and second chips 20 and 60 of which the sizes are equal to or different from each other are embedded in the first and second core substrates 10 and 50, respectively, and the insulating layers 32, 42, and 72 having the conductive bumps 31, 41, and 71 formed therein are laminated on the first core substrates 10, between the first and second core substrates 10 and 50, and under the second core substrate 50, respectively. Therefore, the pads 21 and 61 of the chips 20 and 60 and the circuit patterns 11 and 51 of the core substrates 10 and 50 can be connected to the copper foil patterns 30a and 70a serving as external circuit patterns.

In the related art, to electrically connect the circuit patterns of the chips and the core substrates to external circuit patterns, the insulating layers formed of prepreg are laminated on the core substrates having chips embedded therein, and the via holes are formed by a laser drill method or the like. Therefore, since it is difficult to process the via holes at accurate positions when the via holes are formed, a reduction in yield and reliability caused by connection defects may occur. In this embodiment, however, when the plurality of chips are vertically laminated, the insulating layers 32, 42, and 72 having the conductive bumps 31, 41, and 71 formed therein are laminated on and under the core substrates 10 and 50 having the chips 20 and 60 embedded therein such that the interlayer electrical connection is achieved. Therefore, the process of forming the via holes in the related art can be removed, which makes it possible to simplify the manufacturing process. Further, it is possible to enhance a production yield and the reliability of products.

### Second Embodiment

Referring to FIG. 2, a PCB having chips embedded therein according to a second embodiment will be described. In the second embodiment, the descriptions of the same components as those of the first embodiment will be omitted.

FIG. 2 is a cross-sectional view of the PCB having chips embedded therein according to the second embodiment of the invention.

As shown in FIG. 2, the PCB having chips embedded therein according to the second embodiment has almost the same construction as the PCB having chips embedded therein according to the first embodiment. However, the PCB having chips embedded therein according to the second embodiment is different from the PCB having chips embedded therein according to the first embodiment in that the first pads 21 are not provided on the top surface of the first chip 20, but is provided on the bottom surface of the first chip 20.

That is, the PCB having chips embedded therein according to the second embodiment of the invention includes a first core substrate 10 which has a first chip 20 embedded therein, the first chip 20 having a plurality of first pads 21 provided on the bottom surface thereof, and first circuit patterns 11 provided on both surfaces thereof; and a second core substrate 50 which is disposed under the first core substrate 10 so as to be spaced at a predetermined distance from the first core substrate 10 and has a second chip 60 embedded therein, the second chip 60 having a plurality of second pads 61 provided on the bottom surface thereof, and second circuit patterns 51 provided on both surfaces thereof.

On the first core substrate 10, a first insulating layer 32 is laminated. The first insulating layer 32 has a plurality of conductive bumps 31 formed therein, the conductive bumps 31 passing through the first insulating layer 32 and being connected to the first circuit patterns 11 formed on the top surface of the first core substrate 10.

Between the first core substrate 10 and the second core substrate 50, a second insulating layer 42 is laminated. The second insulating layer 42 has a plurality of second conductive bumps 41 formed therein, the second conductive bumps 41 passing through the second insulating layer 42. The second conductive bumps 41 connect the first circuit patterns 11 and the first pads 21 provided on the bottom surface of the first core substrate 10 to the second circuit patterns 51 provided on the top surface of the second core substrate 50. The first pads 21 may be one-to-one connected to the second conductive bumps 41.

Under the second core substrate 50, a third insulating layer 72 is laminated. The third insulating layer 72 has a plurality of third conductive bumps 71 formed therein, the third conductive bumps 71 passing through the third insulating layer 72. The third conductive bumps 71 are connected to the second circuit patterns 51 and the second pads 61 provided on the bottom surface of the second core substrate 50. The second pads 61 may be one-to-one connected to the third conductive bumps 71.

On the surfaces of the first insulating layer 32 and the third insulating layer 72, first copper foil patterns 30a and third copper foil patterns 70a are formed so as to be connected to the first conductive bumps 31 and the third conductive bumps 71, respectively.

In the PCB having chips embedded therein according to the second embodiment, it is possible to obtain the same operation and effect as the first embodiment. While the PCB having chips embedded therein according to the first embodiment has a structure which is favorable to a multi-pin chip, the PCB having chips embedded therein according to the second embodiment has a structure which is favorable to both of a multi-pin chip and a single-pin chip.

### Third Embodiment

Referring to FIG. 3, a PCB having chips embedded therein according to a third embodiment of the invention will be described. In the third embodiment, the descriptions of the same components as those of the second embodiment will be omitted.

FIG. 3 is a cross-sectional view of the PCB having chips embedded therein according to the third embodiment of the invention.

As shown in FIG. 3, the PCB having chips embedded therein according to the third embodiment has almost the same construction as the PCB having chips embedded therein according to the second embodiment. However, the PCB having chips embedded therein according to the third embodiment is different from the PCB having chips embedded therein according to the second embodiment in that the first copper foil patterns 30a are not formed on the first insulating layer 32, and a third core substrate 80 and a fourth insulating layer 102 are additionally laminated on the first insulating layer 32.

The third core substrate 80 has a third cavity 82 perforated in a predetermined portion thereof, and a third chip 90 is inserted into the third cavity 82. Between the third cavity 82 and the third chip 90, a third filler 92 is filled so as to fix the third chip 90.

The third chip 90 has a plurality of third pads 91 provided on the top surface thereof.

The third circuit patterns 81 provided on the bottom surface of the third core substrate 80 are connected to the first conductive bumps 31 formed in the first insulating layer 32.

The fourth insulating layer 102 has a plurality of fourth conductive bumps 101 formed therein, the fourth conductive bumps 101 passing through the fourth insulating layer 102. The fourth conductive bumps 101 are connected to the third circuit patterns 81 and the third pads 91 provided on the top surface of the third core substrate 80.

On the fourth insulating layer 102, fourth copper foil patterns 100a are formed so as to be connected to the fourth conductive bumps 101.

In the PCB having chips embedded therein according to the third embodiment, the sizes of the laminated chips 20, 60, and 90 and the number, arrangement, pitch, and direction of pads 21, 61, and 91 can be changed in various manners.

In the PCB having chips embedded therein according to the third embodiment, it is possible to obtain the same operation and effect as the first embodiment. Further, since the number of laminated chips is larger than in the first and second embodiments, the PCB can have a variety of functions.

Method of Manufacturing PCB Having Chips Embedded Therein

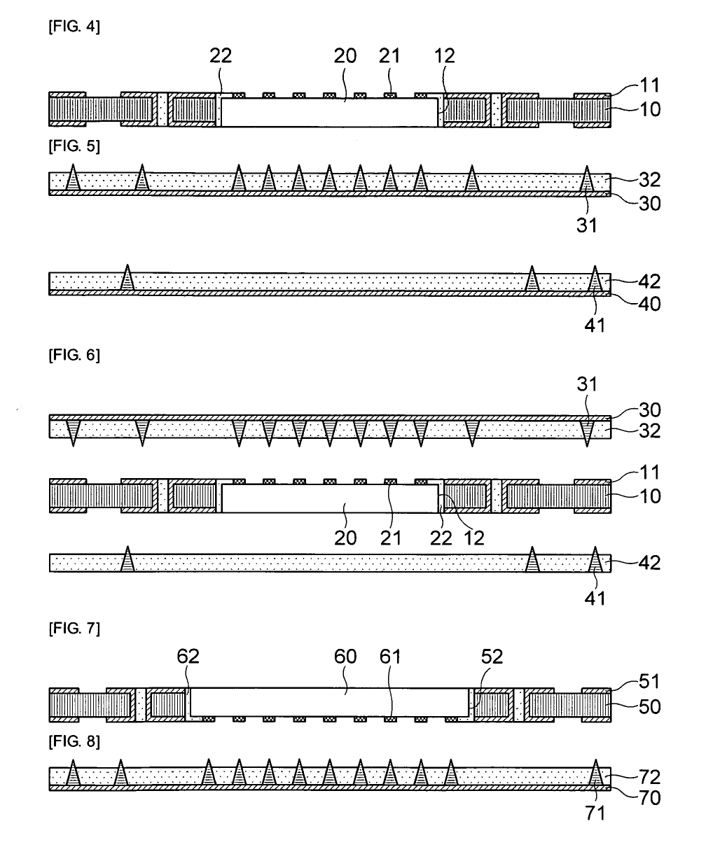

Referring to FIGS. 4 to 11, a method of manufacturing the PCB having chips embedded therein according to the first embodiment will be described.

FIGS. 4 to 11 are process diagrams sequentially showing a method of manufacturing the PCB having chips embedded therein according to the first embodiment.

First, as shown in FIG. 4, a first core substrate 10 is provided, which has a first chip 20 embedded therein, the first chip 20 having a plurality of first pads 21 provided on the top surface thereof, and first circuit patterns 11 provided on both surfaces thereof. The first pads 21 provided on the first chip 20 may be balls or bumps formed of Au, Cu, Sn, or Sn-based alloy with a low or high melting point.

Although not shown, the first core substrate 10 having the chip 20 embedded therein may be provided through the following process.

First, a first cavity 12 is perforated in a predetermined portion of the first core substrate 10 having the first circuit patterns 11 provided thereon. Then, a carrier film (not shown) is attached on one surface of the first core substrate 10, and the first chip 20 having the first pads 21 provided thereon is inserted into the first cavity 12 so as to be fixed to the carrier film. Next, a first filler 22 is filled between the first cavity 12 and the first chip 20, and the carrier film is removed.

Then, as shown in FIG. 5, a first copper foil layer 30 and a second copper foil layer 40 are prepared.

Next, a plurality of first conductive bumps 31 are formed on the first copper foil layer 30, and a plurality of second conductive bumps 41 are formed on the second copper foil layer 40. The first and second conductive bumps 31 and 41 may be formed of Ag, Cu, Sn, Au, or Sn-based alloy with a low melting point. Further, the first and second conductive bumps 31 and 41 may be formed of conductive epoxy obtained by adding a conductive material into epoxy, instead of the above-described metals such as Ag and so on.

Since the first conductive bumps 31 are formed so as to connect the first circuit patterns 11 of the first core substrate 10 and the first pads 21 of the first chip 20 to external circuit patterns and so on, it is preferable that the first conductive bumps 31 are formed in positions corresponding to the first circuit patterns 11 and the first pads 21. In particular, the first conductive bumps 31, which are to be connected to the first pads 21, may be formed so as to correspond to the first pads 21 one to one.

Further, since the second conductive bumps 41 are formed so as to connect the interlayer circuit patterns, it is preferable that the second conductive bumps 41 are formed in positions corresponding to the first circuit patterns 11.

Preferably, the first and second conductive bumps 31 and 41 are formed in a shape of which the upper end is sharp, for example, in a conical shape such that the first and second conductive bumps 31 and 41 penetrate the first and second insulating layers 32 and 42, respectively.

Next, a first insulating layer 32 is formed on the first copper foil layer 30 such that the first conductive bumps 31 penetrate the first insulating layer 32 so as to be exposed, and a second insulating layer 42 is formed on the second copper foil layer 40 such that the second conductive bumps 42 penetrate the second insulating layer 42 so as to be exposed.

The first and second insulating layers 32 and 42 may be formed of prepreg or ABF. Further, the insulating layers 32 and 42 may be formed in a sheet shape so as to be positioned on the first and second copper foil layers 30 and 40, respectively.

Next, as shown in FIG. 6, the second copper foil layer 40 is removed from the second insulating layer 42. Then, the first copper foil layer 30 provided on one surface of the first insulating layer 32, through which the first conductive bumps 31 pass, is disposed above the first core substrate 10, and the second insulating layer 42 through which the second conductive bumps 41 pass is disposed under the first core substrate 10.

Preferably, the first and second insulating layers 32 and 42 are disposed in such a manner that the exposed ends of the first and second conductive bumps 31 and 41 are directed to the first core substrate 10.

Then, as shown in FIG. 7, a second core substrate 50 is provided. The second core substrate 50 has a second chip 60 embedded therein, the second chip 60 having a plurality of second pads 61 provided on the bottom surface thereof, and second circuit patterns 51 provided on both surfaces thereof.

Further, as shown in FIG. 8, a third copper foil layer 70 is prepared, and a plurality of third conductive bumps 71 are formed on the third copper foil layer 70. Preferably, the third conductive bumps 71 are formed in a conical shape of which the upper end is sharp.

Since the third conductive bumps 71 are formed so as to connect the second circuit patterns 51 of the second core substrate 50 and the second pads 61 of the second chip 60 to external circuit patterns, it is preferable that the third conductive bumps 71 are formed in positions corresponding to the second circuit patterns 51 and the second pads 61. At this time, the third conductive bumps 71 which are to be connected to the second pads 61 may be formed so as to correspond to the second pads 61 one to one.

Next, a third insulating layer 72 is formed on the third copper foil layer 70 such that the third conductive bumps 71 penetrate the third insulating layer 72 so as to be exposed.

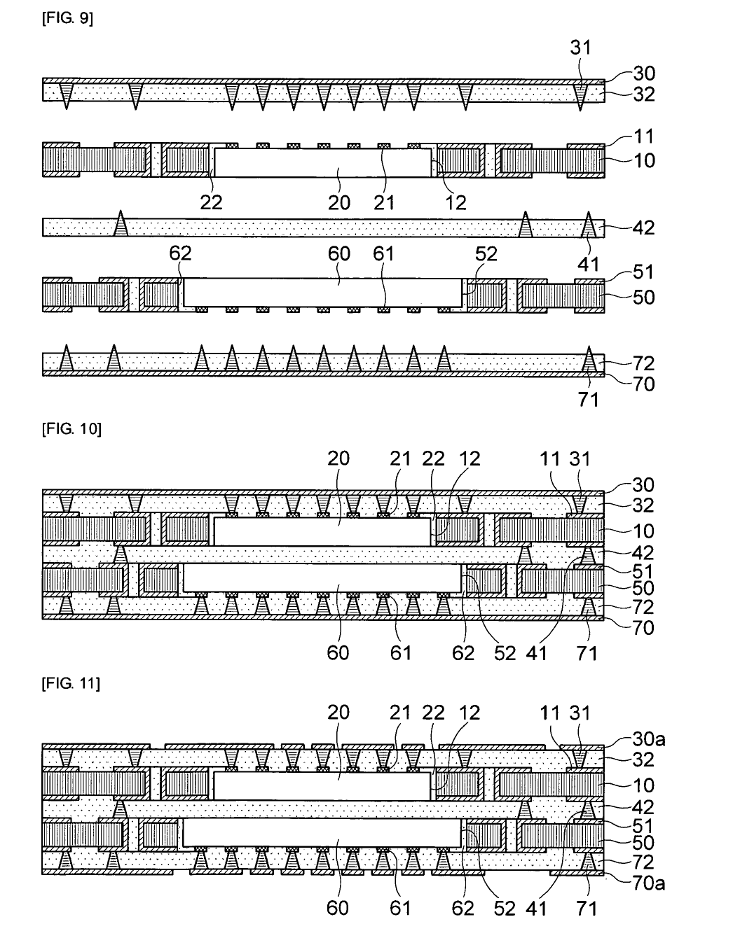

Then, as shown in FIG. 9, the second core substrate 50 having the second chip 60 embedded therein is disposed under the second insulating layer 42.

Further, the third copper foil layer 70, on which the third insulating layer 72 having the third conductive bumps 71 formed therein is provided, is disposed under the second core substrate 50. At this time, the exposed ends of the conductive bumps 71 are directed to the second core substrate 50.

Then, as shown in FIG. 10, the first copper foil layer 30 having the first conductive bumps 31 and the first insulating layer 32 provided thereon, the first core substrate 10 having the first chip 20 embedded therein, the second insulating layer 42 having the second conductive bumps 41 formed therein, the second core substrate 50 having the second chip 60 embedded therein, and the third copper coil layer 70 having the third conductive bumps 71 and the third insulating layer 72 provided thereon are laminated and are then heated and pressurized.

Accordingly, the interlayer circuit patterns 11 and 51 and the chip pads 21 and 61 can be connected to each other through the conductive bumps 31, 42, and 71.

Next, as shown in FIG. 11, the first copper foil layer 30 and the third copper foil layer 70 are partially removed so as to form first and third copper foil patterns 30a and 70a which are to be connected to the first and third conductive bumps 31 and 71.

According to the method of manufacturing the PCB having chips embedded therein, when the plurality of chips are vertically laminated, the interlayer electrical connection can be achieved only by laminating the insulating layers 32, 42, and 72 on and under the core substrates 10 and 50 having the chips therein. Therefore, the process of forming via holes for the interlayer connection in the related art can be omitted, which makes it possible to reduce the manufacturing cost and time of the PCB. Accordingly, it is possible to enhance the production yield and reliability of products.

According to the invention, when the plurality of chips are laminated, the interlayer connection can be achieved only by laminating the insulating layers having the conductive bumps formed therein on and under the core substrates having chips therein, which makes it possible to reduce the manufacturing time and process. Therefore, it is possible to enhance a production yield and reliability of the PCB.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A printed circuit board (PCB) having chips embedded therein, comprising:
a first core substrate that has a first chip embedded therein, the first chip having a plurality of first pads provided on the top surface thereof, and first circuit patterns provided on both surfaces thereof;
a second core substrate that is disposed under the first core substrate so as to be spaced at a predetermined space from the first core substrate and has a second chip embedded therein, the second chip having a plurality of second pads provided on the bottom surface thereof, and second circuit patterns provided on both surfaces thereof;
a first insulating layer that is laminated on the first core substrate and has a plurality of first conductive bumps formed therein, the first conductive bumps passing through the first insulating layer and being connected to the first circuit patterns and the first pads;
a second insulating layer that is laminated between the first core substrate and the second core substrate and has a plurality of second conductive bumps formed therein, the second conductive bumps passing through the second insulating layer and connecting the first circuit patterns to the second circuit patterns; and
a third insulating layer that is laminated under the second core substrate and has a plurality of third conductive bumps formed therein, the third conductive bumps passing through the third insulating layer and being connected to the second circuit patterns and the second pads.

2. The PCB according to claim 1 further comprising:
copper foil patterns that are formed on the surfaces of the first and third insulating layers so as to be connected to the first and third conductive bumps.

3. The PCB according to claim 1, wherein the first core substrate has a first cavity perforated in a predetermined portion thereof, and the first chip is inserted into the first cavity.

4. The PCB according to claim 1 further comprising:
a first filler that is filled between the first chip and the first cavity so as to fix the first chip.

5. The PCB according to claim 1, wherein the second core substrate has a second cavity perforated in a predetermined portion thereof, and the second chip is inserted into the second cavity.

6. The PCB according to claim 5 further comprising:
a second filler that is filled between the second chip and the second cavity so as to fix the second chip.

7. The PCB according to claim 1, wherein the first pads are one-to-one connected to the first conductive bumps.

8. The PCB according to claim 1, wherein the second pads are one-to-one connected to the third conductive bumps.

9. The PCB according to claim 1, wherein the first to third conductive bumps are formed of any one selected from the group consisting of conductive epoxy, Ag, Cu, Sn, Au, and Sn-based alloy.

10. The PCB according to claim 9, wherein the Sn-based alloy is composed of any one selected from the group consisting of AuSn, SnSb, SnAg, SnPb, SnBi, and SnIn.

11. The PCB according to claim 1, wherein the first and second pads are balls or bumps formed of any one selected from the group consisting of Au, Cu, Sn, and Sn-based alloy.

12. The PCB according to claim 1, wherein the first to third insulating layers are formed of prepreg or ABF (Ajinomoto Build-up Film).

13. A PCB having chips embedded therein, comprising:
a first core substrate that has a first chip embedded therein, the first chip having a plurality of first pads provided on the bottom surface thereof, and first circuit patterns provided on both surfaces thereof;
a second core substrate that is disposed under the first core substrate so as to be spaced at a predetermined space from the first core substrate and has a second chip embedded therein, the second chip having a plurality of second pads provided on the bottom surface thereof, and second circuit patterns provided on both surfaces thereof;
a first insulating layer that is laminated on the first core substrate and has a plurality of first conductive bumps formed therein, the first conductive bumps passing through the first insulating layer and being connected to the first circuit patterns;
a second insulating layer that is laminated between the first core substrate and the second core substrate and has a plurality of second conductive bumps formed therein, the second conductive bumps passing through the second insulating layer and connecting the first circuit patterns and the first pads to the second circuit patterns; and
a third insulating layer that is laminated under the second core substrate and has a plurality of third conductive bumps formed therein, the third conductive bumps passing through the third insulating layer and being connected to the second circuit patterns and the second pads.

14. The PCB according to claim 13 further comprising:
copper foil patterns that are formed on the surfaces of the first and third insulating layers so as to be connected to the first and third conductive bumps.

15. The PCB according to claim 13, wherein the first pads are one-to-one connected to the second conductive bumps.

16. The PCB according to claim 13, wherein the second pads are one-to-one connected to the third conductive bumps.

17. The PCB according to claim 13 further comprising:
a third core substrate that is laminated on the first insulating layer and has a third chip embedded therein, the third chip having a plurality of third pads provided on the top surface thereof, and third circuit patterns provided on both surfaces thereof; and
a fourth insulating layer that is laminated on the third core substrate and has a plurality of fourth conductive bumps formed therein, the fourth conductive bumps passing through the fourth insulating layer and being connected to the third circuit patterns and the third pads.

18. A method of manufacturing a PCB having chips embedded therein, comprising:
providing a first core substrate, the first core substrate having a first chip embedded therein, the first chip having a plurality of first pads provided on the top surface thereof, and first circuit patterns provided on both surfaces thereof;
disposing a first copper foil layer and a second insulating layer above and under the first core substrate, the first copper foil layer having a first insulating layer provided on one surface thereof, the first insulating layer having a plurality of conductive bumps formed therein, the conductive bumps corresponding to the first circuit patterns and the first pads, the second insulating layer having a plurality of second conductive bumps formed therein, the second conductive bumps corresponding to the first circuit patterns;
disposing a second core substrate under the second insulating layer, the second core substrate having a second chip embedded therein, the second chip having a plurality of second pads provided on the bottom surface thereof, and second circuit patterns provided on both surfaces thereof;
disposing a third copper foil layer under the second core substrate, the third copper foil layer having a third insulating layer provided on one surface thereof, the third insulating layer having a plurality of third conductive bumps formed therein, the third conductive bumps corresponding to the second circuit patterns and the second pads; and
laminating the first core substrate, the first copper foil layer, the second insulating layer, the second core substrate, and the third copper foil layer.

19. The method according to claim 18, wherein the first pads and the first conductive pads correspond to each other one to one.

20. The method according to claim 18, wherein the second pads and the third conductive bumps correspond to each other one to one.

21. The method according to claim 18 further comprising:
before the disposing of the first copper foil layer and the second insulating layer,
forming the first conductive bumps on the first copper foil layer, and forming the second conductive bumps on a separate second copper foil layer;
forming the first insulating layer on the first copper foil layer such that the first conductive bumps penetrate the first insulating layer so as to be exposed, and forming the second insulating layer on the second copper foil layer such that the second conductive bumps penetrate the second insulating layer so as to be exposed; and
removing the second copper foil layer from the second insulating layer.

22. The method according to claim 21, wherein the first and second conductive bumps are formed in a conical shape.

23. The method according to claim 21 further comprising:
before the disposing of the third copper foil layer;
forming the third conductive bumps on the third copper foil layer; and
forming the third insulating layer on the third copper foil layer such that the third conductive bumps penetrate the third insulating layer so as to be exposed.

24. The method according to claim 18 further comprising:
after the laminating of the first core substrate, the first copper foil layer, the second insulating layer, the second core substrate, and the third copper foil layer,
heating and pressurizing the PCB.

25. The method according to claim 24 further comprising:
after the heating and pressurizing of the PCB,
partially removing the first and third copper foil layers so as to form copper foil patterns which are to be connected to the first and third conductive bumps.

26. The method according to claim 18, wherein the first to third conductive bumps are formed of any one selected from the group consisting of conductive epoxy, Ag, Cu, Sn, Au, and Sn-based alloy.

27. The method according to claim 18, wherein the first and second pads are balls or bumps formed of any one selected from the group consisting of Au, Cu, Sn, and Sn-based alloy.

28. The method according to claim 18, wherein the first to third insulating layers are formed of prepreg or ABF.
